(19) United States
(12) Patent Application Publication
(10) Pub. No.: US 2012/0001300 A1
(43) Pub. Date: Jan. 5, 2012

(54) METHOD OF MANUFACTURING SEMICONDUCTOR DEVICE AND SEMICONDUCTOR DEVICE

(75) Inventors: Takayuki Ito, Oita-ken (JP); Kenichi Yoshino, Oita-ken (JP); Tatsuya Ishida, Oita-ken (JP); Tatsuya Naito, Oita-ken (JP)

(73) Assignee: KABUSHIKI KAISHA TOSHIBA, Tokyo (JP)

(21) Appl. No.: 13/048,169

(22) Filed: Mar. 15, 2011

(30) Foreign Application Priority Data
Jul. 5, 2010 (JP) 2010-153145

(51) Int. Cl. H01L 29/38; H01L 21/20

(52) U.S. Cl. 257/607; 438/479; 257/E21.134; 257/E29.105

(57) ABSTRACT

In a method of manufacturing a semiconductor device, forming a film of amorphous Si on a substrate including an insulating upper surface; injecting a first impurity of a first conductivity in a first region and a second region of the film; crystallizing the film by melting and solidifying the film and activating the first impurity by scanning a first laser light in a first direction and radiating the first laser light over the film; injecting a second impurity of a second conductivity at a higher concentration than the first impurity, the second impurity being a lighter element than the first impurity in the first region with masking the second region; and activating the second impurity.

### CROSS-REFERENCE TO RELATED APPLICATION

This application is based upon and claims the benefit of priority from the prior Japanese Patent Application No. 2010-153145 filed on Jul. 5, 2010, the entire contents of which are incorporated herein by reference.

### BACKGROUND

Embodiments described herein related generally to a method of manufacturing a semiconductor device and the semiconductor device.

In recent years, in order to accelerate and increase resolution in a liquid display device, a contact image sensor and the like and to realize a three dimensional IC, a development has been progressing regarding techniques for forming a high performance semiconductor element on an insulative substrate such as glass or a substrate in which an insulating film is formed over elements and wirings.

In this type of semiconductor element, conventionally, an amorphous Si (hereinbelow referred to as a-Si) semiconductor that can be formed under a low temperature and has a superior property for mass production has been used. However, since it has a low dielectric property and it is difficult to obtain a satisfactory accelerating property, a usage of a polycrystal Si (hereinbelow referred to as poly-Si) semiconductor is being considered in various respects.

A poly-Si semiconductor can be obtained by, for example, radiating a high intensity heat ray such as excimer laser light onto an a-Si semiconductor film, melting and solidifying the same, and crystallizing the same. According to a method as above, though having a small grain diameter, a crystal grain in which only a small number of crystal defects exist can be obtained, and a poly-Si semiconductor film having a relatively high quality can be formed. However, a grain boundary that exists irregularly functions as a serious trap for carriers, and there is a problem in that a favorable electric property cannot be obtained.

Thus, the a-Si semiconductor film is scanned by a laser beam pulse thereby to melt and solidify, and by controlling a direction of crystal growth, an improvement in the electric property can be expected.

### BRIEF DESCRIPTION OF THE DRAWINGS

FIG. 1 is a perspective view of a substrate having a poly-Si film in which an active region of a semiconductor device of an embodiment is to be formed;

FIG. 2 is a flow chart showing a manufacturing process of the semiconductor device of an embodiment of the present invention;

FIG. 3 is a diagram showing the manufacturing process of the semiconductor device of an embodiment of the present invention;

FIG. 4 is a diagram showing a manufacturing process of a semiconductor device of a comparative example;

FIG. 5 is a perspective view of a substrate having a poly-Si film in which an active region of a semiconductor device of an embodiment of the present invention is to be formed;

FIG. 6 is a flowchart showing a manufacturing process of the semiconductor device of an embodiment of the present invention; and

FIG. 7 is a diagram showing the manufacturing process of the semiconductor device of an embodiment of the present invention.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

Hereinbelow, embodiments of the present invention will be described with reference to the drawings.

### First Embodiment

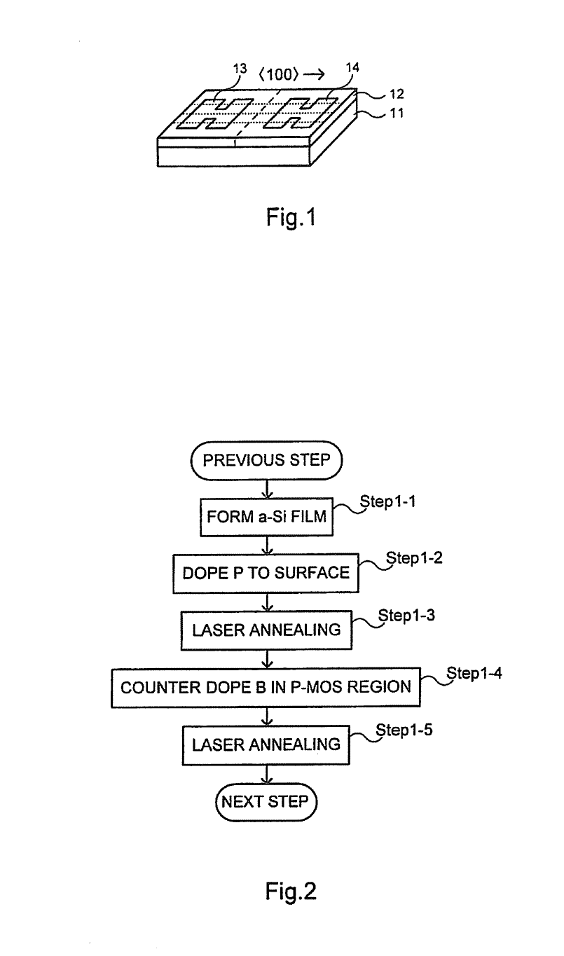

FIG. 1 shows a perspective view of a substrate having a poly-Si film in which active regions are to be formed of a semiconductor device of this embodiment. As shown in FIG. 1, on a substrate 11 having an insulating surface, such as an insulative substrate such as glass or a substrate on which an insulating film is formed over elements and wirings, a poly-Si film 12 that is oriented, for example, in a <100> axis direction is formed.

In the poly-Si film 12 of a p-MOSFET forming region 13 in which a p-type MOSFET is to be formed, phosphorus (P) that is a V-group element that will be an n-type impurity and boron (B) that is a III-group element that will be a p-type impurity and is a lighter element than phosphorus (P) are ion injected, such that boron (B) has higher concentration than phosphorus (P). In the poly-Si film 12 of an n-MOSFET forming region 14 in which an n-type MOSFET is to be formed, phosphorus (P) is ion injected.

The p-MOSFET forming region 13 and the n-MOSFET forming region 14 as above have their patterns defined such that channel directions of elements to be formed respectively are directed to the <100> axis direction. Note that sizes of Si crystal grains of the p-MOSFET forming region 13 and the n-MOSFET forming region 14 are almost uniform.

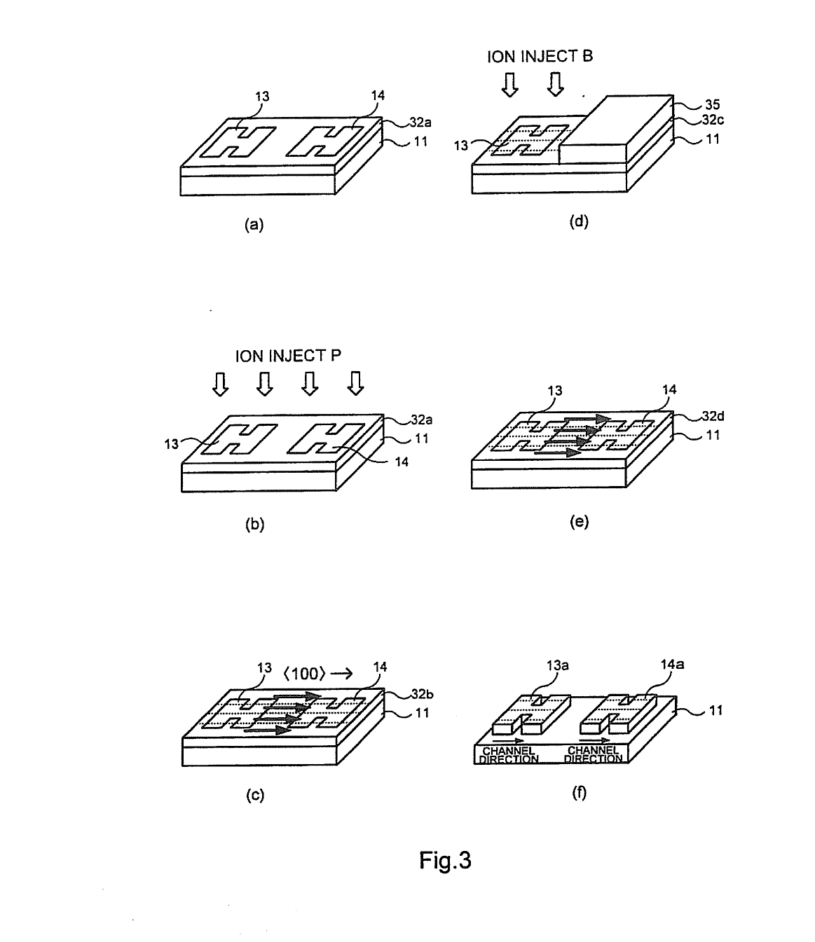

The semiconductor device of the present embodiment is formed by a process as shown in a flowchart of FIG. 2 and FIGS. 3(a) to (f).

As shown in FIG. 3(a), an a-Si film 32a is formed on the substrate 11 (Step 1-1).

As shown in FIG. 3(b), phosphorus (P) is ion injected into the p-MOSFET forming region 13 and the n-MOSFET forming region 14 of the a-Si film 32a using a known ion injection technique (Step 1-2). As an ion injection condition, for example, an acceleration energy is set at 25 keV, and a dosage is set at 1×10¹³ cm⁻².

As shown in FIG. 3(c), by using an Nd:YAG laser that is capable of oscillation of short pulse of, for example, 100 nsec, laser light is scanned (in parallel) in one direction over the p-MOSFET forming region 13 and the n-MOSFET forming region 14 of an a-Si film 32b into which phosphorus (P) has been ion injected and radiating the laser light thereon, laser annealing is carried out (Step 1-3). By melting and solidifying the a-Si film 32b and crystallizing the same with this laser annealing, a poly-Si film 32c having uniform crystal grains in the p-MOSFET forming region 13 and the n-MOSFET forming region 14 is formed, and the ion injected phosphorus (P) is electrically activated.

The a-Si film 32b is locally melted and solidified by the radiation of the laser light, and is crystal grown in a scanning direction. Accordingly, the crystal grains are aligned in one direction, and a constant orientation is achieved between adjacent crystal grains; thus, crystal grains that are homogenized and elongated in a film direction can be formed. The crystal grains to be formed are likely to have their <100> axis direction coincide with the scanning direction, so the poly-Si film 32c that is oriented in the <100> axis direction can be obtained.

This is assumed as being due to the following reason. In an Si crystal growth, a vacancy into which an Si atom can enter exists at a distal end of an uncombined hand of a crystal growth surface, and the crystal growth progresses by repetition of the Si atom in the vicinity of the vacancy breaking off an Si bond of an a-Si and entering the vacancy position. That is, as the number of the uncombined hand is larger, the Si atom is more likely to enter the vacancy position at the distal end, and stability of crystallization is increased thereby.

In a case of a {100} surface growth, two uncombined hands exist in the crystal growth surface irrelevant to an atom layer. In cases of {111} and {110} surface growths, on the other hand, a case with one uncombined hand and a case with three uncombined hands appear alternately in respective atom layers in the crystal growth surface. In the case with three uncombined hands, the stability of crystallization increases; however, in the case with one uncombined hand, a reversed process in which the Si atom in the vacancy position breaks off the bond again to become amorphous becomes dominant, so the crystallization becomes unstable.

As a result, the {100} surface growth, in which crystallization is stabilized and the uncombined hand stably exists in any atom surface has the fastest growth speed, and is oriented with priority in the <100> axis direction.

The condition for laser annealing as above is set to, for example, a beam shape of 0.2 mm×2 mm, scan in a short axis direction, and control such that a surface temperature of the a-Si film 32b becomes 1000° C.

It is preferable that the surface temperature of the a-Si film 32b be controlled to be 800 to 1400° C. This is due to the fact that if the surface of the a-Si film 32b is lower than 800° C., it becomes difficult to enhance solid phase growth; and if it exceeds 1400° C., a surface morphology is degraded due to exceeding a melting point of Si.

Further, it is preferable that a temperature of an upper surface of the substrate 11 be 400° C. or less. If the temperature of the substrate 11 exceeds 400° C., since a consideration for heat resistivity needs to be made, a freedom of design of the substrate 11 is decreased, choices of a substrate material become limited, and lowering cost of the semiconductor device becomes difficult. Further, by suppressing the temperature of the substrate 11 upon the laser annealing as above, in the substrate in which the insulating film is formed over the elements and the wirings, it becomes possible to use a metal layer of, for example, Cu and Al having a low heat resistivity.

As shown in FIG. 3(d), the n-MOSFET forming region 14 is masked with a resist 35, and boron (B) that is a lighter element than phosphorus (P) is ion injected (counter doped) to the poly-Si film 32c of the p-MOSFET forming region 13 that is opened using a publicly known ion injection technique (Step 1-4). At this occasion, as the ion injection condition, for example, the acceleration energy may be set at 10 keV, and the dosage may be set at 2×10¹³ cm⁻².

After the resist 35 is removed, as shown in FIG. 3(e), similar to Step 1-3, the laser annealing is performed on a poly-Si film 32d into which boron (B) has been ion injected by scanning the laser light and radiating the same, and boron (B) that has been ion injected in the p-MOSFET forming region 13 is thereby electrically activated (Step 1-5).

At this occasion, the laser annealing is performed under the same condition as, for example, Step 1-3. Note that, the present invention is not limited to such a condition. By this laser annealing, although boron (B) of the p-MOSFET forming region 13 is activated in a high concentration, since it is sufficiently crystallized, no further grain growth takes place in the same condition as the previous laser annealing, and the size of the crystal grains does not change.

Accordingly, as shown in FIG. 1, the poly-Si film 12 in which the active regions of the semiconductor device is to be formed is formed on the substrate 11.

As a comparative example, a case in which p-type and n-type impurities are respectively ion injected into a p-MOSFET forming region and an n-MOSFET forming region, and crystallization and activation are performed by laser annealing is exemplified.

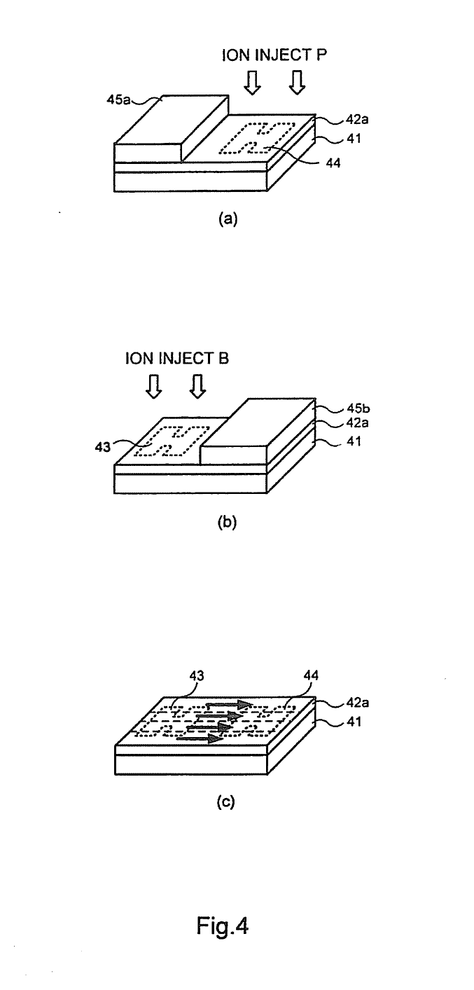

As shown in FIG. 4(a), on a substrate 41 onto which an a-Si film 42a is formed, a p-MOSFET forming region 43 is masked with a resist 45a, and phosphorus (P) is ion injected into an n-MOSFET forming region 44 that is opened using a publicly known ion injection technique. As an ion injection condition, for example, an acceleration energy is set at 25 keV, and a dosage is set at 1×10¹³ cm⁻².

As shown in FIG. 4(b), after the resist 45a is removed, the n-MOSFET forming region 44 is masked with a resist 45b, and boron (B) is ion injected into the p-MOSFET forming region 43 that is opened using a known ion injection technique. At this occasion, as the ion injection condition, for example, the acceleration energy is set at 10 keV, and the dosage is set at 1×10¹³ cm⁻².

As shown in FIG. 4(c), after the resist 45b is removed, annealing using laser radiation is performed under the same condition as that of the first embodiment. By the annealing using the laser radiation, the a-Si film 42a is melted and solidified and a poly-Si film 42b is formed (crystallized) in the p-MOSFET forming region 43 and the n-MOSFET forming region 44, and the ion injected boron (B) and phosphorus (P) are electrically activated respectively.

In the poly-Si film 42b formed according to the above, similar to the first embodiment, although crystal grains are grown in a scanning direction of the laser light, sizes of the crystal grains in the p-MOSFET forming region 43 and the n-MOSFET forming region 44 are apparently different. For example, in the n-MOSFET forming region 44, an average grain diameter is about 100 nm, whereas in the p-MOSFET forming region 43, the average grain diameter is about 10 nm.

This is assumed as being due to a speed of solid phase growth upon crystallization by melting and solidifying being different depending on the impurity that is introduced into the a-Si film; that is, the speed of solid phase growth being faster in a region where phosphorus (P) has been introduced than in a region where boron (B) has been introduced.

Accordingly, with the crystal grain diameters being different, a degree of carrier mobility becomes greatly different and an etching speed upon a patterning processing using an RIE (Reactive Ion Etching) and the like is changed, thereby accuracy in the processing becomes varied.

On the other hand, in the first embodiment, in the a-Si film 32a, by introducing phosphorus (P) in both of the p-MOSFET forming region 13 and the n-MOSFET forming region 14 and crystallizing the same by the laser annealing, it becomes possible to obtain uniform crystal grains that are larger than upon the introduction of boron (B) and oriented in one direction.

As shown in FIG. 3(f), the poly-Si film 12 obtained as above is patterned using the RIE and the like, thereby respectively forming active regions of the p-MOSFET 13a and active regions of the n-MOSFET 14a. The patterns thereof are defined such that a channel direction of a semiconductor element that is respectively formed and the orientation direction of the poly-Si film 12 come to be in the same direction (parallel).

Moreover, by forming an electrode and the like, a semiconductor element such as a thin-film transistor is formed on the substrate 11, whereby the semiconductor device is manufactured.

According to the present embodiment, since the size and the direction of the crystal grains in the poly-Si film in which the active regions of the semiconductor device are formed become uniform, the processing variation in the electric property, the RIE processing and the like can be decreased, and the variation in the property of the semiconductor device as obtained can be suppressed.

### Second Embodiment

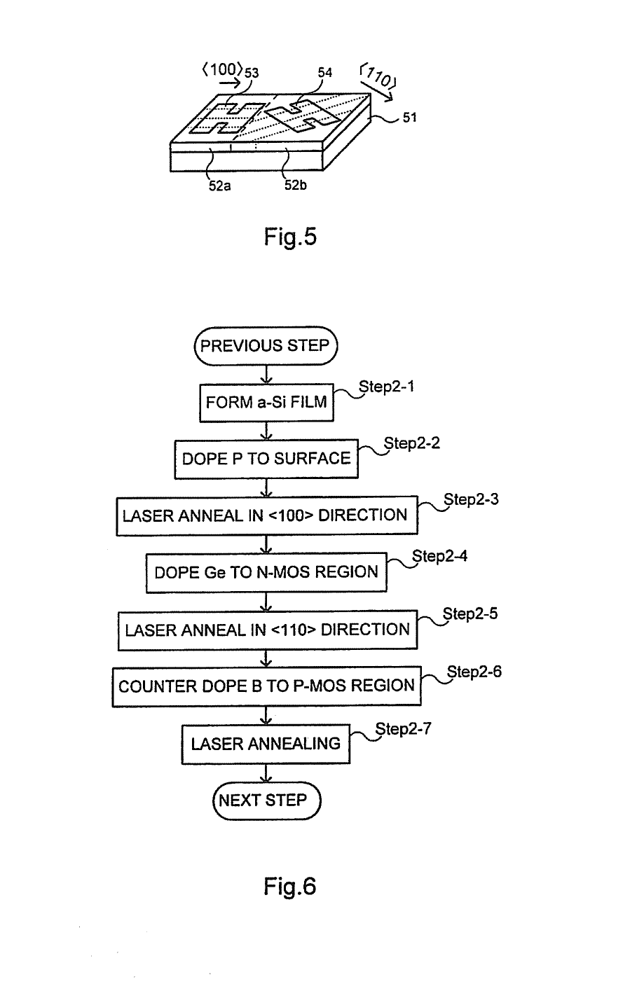

FIG. 5 shows a perspective view of a substrate having a poly-Si film in which active regions are to be formed of a semiconductor device of this embodiment. As shown in FIG. 5, on a substrate 51 having an insulating surface, such as an insulative substrate such as glass or a substrate on which an insulating film is formed over elements and wirings, poly-Si films 52a and 52b are formed.

The poly-Si film 52a of a p-MOSFET forming region 53 in which a p-type MOSFET is to be formed is oriented, for example, in a <100> axis direction, and phosphorus (P) that is a V-group element that will be an n-type impurity and boron (B) that is a III-group element that will be a p-type impurity and is a lighter element than phosphorus (P) are ion injected therein, such that boron (B) has higher concentration than phosphorus (P). The poly-Si film 52b of an n-MOSFET forming region 54 in which an n-type MOSFET is to be formed is oriented, for example, in a <110> axis direction, and phosphorus (P) and Germanium (Ge) that is a IV-group element that will be a non-conductive impurity are ion injected therein.

The p-MOSFET forming region 53 and the n-MOSFET forming region 54 as above have their patterns defined such that a channel direction of an element to be formed respectively therein is directed, for example, to the <100> axis direction and the <110> axis direction. Note that sizes of Si crystal grains of the p-MOSFET forming region 53 and the n-MOSFET forming region 54 are almost uniform.

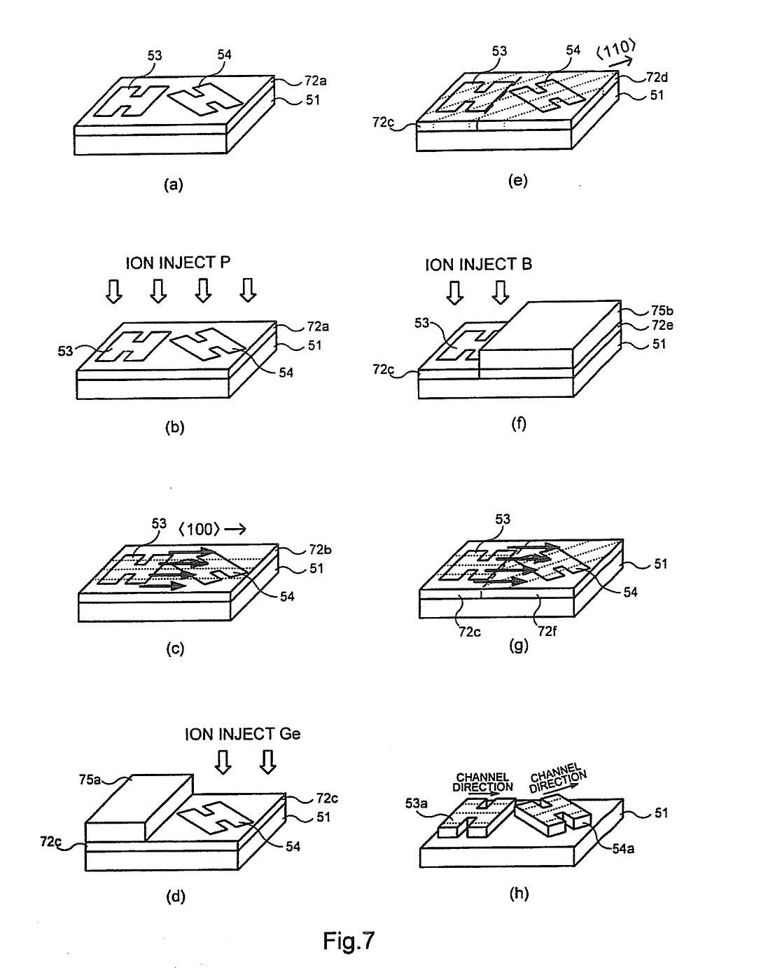

The semiconductor device of the present embodiment is formed by a process as shown in a flowchart of FIG. 6 and FIGS. 7(a) to (h).

As shown in FIG. 7(a), an a-Si film 72a is formed on the substrate 51 (Step 2-1).

As shown in FIG. 7(b), phosphorus (P) is ion injected into the p-MOSFET forming region 53 and the n-MOSFET forming region 54 of the a-Si film 72a using a publicly known ion injection technique (Step 2-2). At this occasion, as an ion injection condition, for example, an acceleration energy is set at 25 keV, and a dosage is set at 1×10¹³ cm⁻², similar to the first embodiment.

As shown in FIG. 7(c), similar to the first embodiment, by using an Nd:YAG laser, laser light is scanned (in parallel) in one direction and radiating over an a-Si film 72b into which phosphorus (P) has been ion injected, and laser annealing is carried out thereby (Step 2-3).

By melting and solidifying the a-Si film 72b and crystallizing the same with this laser annealing, a poly-Si film 72c having uniform crystal grains oriented with priority in <100> in the p-MOSFET forming region 53 and the n-MOSFET forming region 54 is formed, and the ion injected phosphorus (P) is electrically activated.

In the a-Si film 72b, similar to the first embodiment, the crystal grains are grown in the scanning direction and aligned in one direction, and a constant orientation is achieved between adjacent crystal grains; thus, crystal grains that are homogenized and elongated in a film direction can be formed. The crystal grains to be formed are likely to have their <100> axis direction coincide with the scanning direction, so the poly-Si film 72c that is oriented in the <100> axis direction can be obtained.

A condition for the laser annealing as above can be the same as the condition in the first embodiment due to the same reason therefor.

As shown in FIG. 7(d), the p-MOSFET forming region 53 is masked with a resist 75a, and by ion injecting Germanium (Ge) into the n-MOSFET forming region 54 that is opened using a publicly known ion injection technique, a poly-Si film 72c of the opened n-MOSFET forming region 54 is made amorphous to form an a-Si film 72d (Step 2-4). At this occasion, as the ion injection condition, for example, the acceleration energy may be set at 10 keV, and the dosage may be set at 5×10¹⁴ cm⁻².

After the resist 75a is removed, as shown in FIG. 7(e), the laser annealing is performed by scanning the laser light and radiating the same on the p-MOSFET forming region 53 and the n-MOSFET forming region 54, for example, under the same condition as in Step 2-3 but scanning (in parallel) in the <110> axis direction that is different by 45 degrees from the aforementioned condition (Step 2-5).

At this occasion, in the p-MOSFET forming region 53, the poly-Si film 72c that is oriented in the <100> axis direction is already formed. Since phosphorus (P) that enhances solid phase growth has been introduced and the crystal grains are sufficiently grown, no further grain growth takes place in the same condition, and the size of the crystal grains does not change.

On the other hand, in the n-MOSFET forming region 54 in which the a-Si film 72d is formed again, new crystal growth is enhanced in the <110> axis direction that is the laser scanning direction with a {100} surface of the p-MOSFET forming region 53 as a seed thereof. At this occasion, since phosphorus (P) that enhances the solid phase growth has been introduced, the crystal grains can sufficiently be grown similar to the p-MOSFET forming region 53.

Accordingly, by the second laser annealing, the a-Si film 72d is melted and solidified in the n-MOSFET forming region 54, a poly-Si film 72e having uniform crystal grains similar to the p-MOSFET forming region 53 and oriented in the <110> axis direction can be formed.

Similar to the first embodiment, as shown in FIG. 7(f), the n-MOSFET forming region 54 is masked with a resist 75b, and boron (B) that is a lighter element than phosphorus (P) is ion injected (counter doped) to the p-MOSFET forming region 53 that is opened using a publicly known ion injection technique (Step 2-6). At this occasion, as the ion injection condition, for example, the acceleration energy may be set at 10 keV, and the dosage may be set at 2×10¹³ cm⁻², similar to the first embodiment.

As shown in FIG. 7(g), after the resist 75b is removed, for example, under the same condition as Step 2-3, by performing the laser annealing for the third time on a poly-Si film 72f into which boron (B) has been ion injected, boron (B) that has been ion injected in the p-MOSFET forming region 53 is electrically activated (Step 2-7).

At this occasion, by the laser annealing, although boron (B) of the p-MOSFET forming region 53 is activated in a high concentration, since the poly-Si film 72c is sufficiently crystallized already, no further grain growth takes place in the same condition as the first and second laser annealing, and the size of the crystal grains does not change.

Accordingly, as shown in FIG. 5, the poly-Si films 52a and 52b in which the active regions of the semiconductor device are formed are formed on the substrate 51.

Similar to the first embodiment, as shown in FIG. 7(h), the poly-Si films 52a and 52b obtained as above are patterned using the RIE and the like, thereby respectively forming active regions 53a and 54a of the p-MOSFET and the n-MOSFET.

The patterns thereof are defined such that channel directions of the p-MOSFET and the n-MOSFET and the orientation directions of the poly-Si films 52a, 52b come to be in the same direction (parallel). That is, the channel direction of the p-MOSFET is set as the <100> axis direction, along which holes are easily flowed, and the channel direction of the n-MOSFET is set as the <110> axis direction, along which electrons are easily flowed.

Moreover, by forming an electrode and the like, a semiconductor element such as a thin-film transistor is formed on the substrate 51, whereby the semiconductor device is manufactured.

According to the present embodiment, since the size and the directivity of the crystal grains become homogenized, the processing variation in the electric property and in the RIE processing and the like can be decreased, and the variation in the property of the semiconductor device obtained can be suppressed. Further, in the semiconductor device obtained, a degree of electron mobility can be increased, and thereby a further acceleration and lower power consumption become possible.

In these embodiments, although phosphorus (P) that will be the n-type impurity is first ion injected as an impurity in an surface and boron (B) that will be the p-type impurity which is a lighter element than phosphorus (P) is thereafter ion injected (counter doped) in the p-MOSFET forming region, the present invention is not limited to this combination. For example, in place of phosphorus (P), arsenic (As) that is a heavier element than boron (B) may be utilized. Indium (In) that will be the p-type impurity may first be injected in the surface, and P may be counter doped in the n-MOSFET forming region thereafter.

While certain embodiments have been described, these embodiments have been presented by way of example only, and are not intended to limit the scope of the inventions. Indeed, the novel embodiments described herein may be embodied in a variety of other forms; furthermore, various omission, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a film of amorphous Si on a substrate including an insulating upper surface;
injecting a first impurity of a first conductivity in a first region and a second region of the film;
crystallizing the film by melting and solidifying the film and activating the first impurity by scanning a first laser light in a first direction and radiating the first laser light over the film;
injecting a second impurity of a second conductivity at a higher concentration than the first impurity, the second impurity being a lighter element than the first impurity in the first region with masking the second region; and
activating the second impurity.

2. The method of manufacturing a semiconductor device according to claim 1, wherein the first impurity is phosphorus.

3. The method of manufacturing a semiconductor device according to claim 1, wherein a surface temperature of the film is controlled to be 800 to 1400° C., and the upper surface temperature of the substrate is controlled to be 400° C. or less, when the first laser light is to be radiated.

4. The method of manufacturing a semiconductor device according to claim 1, wherein the film that is oriented in a (100) axis direction is formed by scanning the first laser light in the first direction and radiating the first laser light over the film.

5. The method of manufacturing a semiconductor device according to claim 1, wherein the second impurity is boron.

6. The method of manufacturing a semiconductor device according to claim 1, further comprising;
injecting a third impurity of non-conductivity in the second region to be made amorphous after having activated the first impurity and before the injection of the second impurity, and
crystallizing the film by melting and solidifying the film by scanning a second laser light in a second direction different from the first direction and radiating the second laser light over the film.

7. The method of manufacturing a semiconductor device according to claim 6, wherein the third impurity is germanium.

8. The method of manufacturing a semiconductor device according to claim 6, wherein the surface temperature of the film is controlled to be 800 to 1400° C., and the upper surface temperature of the substrate is controlled to be 400° C. or less, when the second laser light is to be radiated.

9. The method of manufacturing a semiconductor device according to claim 6, wherein the second direction is different from the first direction by 45 degrees.

10. The method of manufacturing a semiconductor device according to claim 6, wherein the Si film that is oriented in a (110) axis direction is formed by scanning the second laser light in the second direction and radiating the second laser light over the film.

11. The method of manufacturing a semiconductor device according to claim 1, wherein the second impurity is activated by scanning a third laser light and radiating the third laser light over the film.

12. The method of manufacturing a semiconductor device according to claim 11, wherein the surface temperature of the Si film is controlled to be 800 to 1400° C., when the third laser light is to be radiated.

13. The method of manufacturing a semiconductor device according to claim 11, wherein the upper surface temperature of the substrate is controlled to be 400° C. or less, when the third laser light is to be radiated.

14. A semiconductor device comprising:
a substrate including an insulating upper surface;
a first element formed on the substrate, the first element comprising an active region of the second conductivity including a crystalline Si film oriented in a first direction, the first element into which a first impurity of a first conductivity and a second impurity of a second conductivity that is a lighter element than the first impurity is injected; and
a second element formed in the substrate, the second element comprising an active region of the first conductivity including a crystalline Si film oriented in a second direction into which the first impurity is injected.

15. The semiconductor device according to claim 14, wherein the first direction and the second direction are a <100> axis direction.

16. The semiconductor device according to claim 14, wherein the first impurity is phosphorus.

17. The semiconductor device according to claim 14, wherein the second impurity is boron.

18. The semiconductor device according to claim 14, wherein a third impurity of non-conductivity is injected into the active region of the first conductivity.

19. The semiconductor device according to claim 18, wherein the first direction is a <100> axis direction, and the second direction is a <110> axis direction.

20. The semiconductor device according to claim 18, wherein the third impurity is germanium.
